(19) United States
(12) Patent Application Publication
(10) Pub. No.: US 2007/0184560 A1
(43) Pub. Date: Aug. 9, 2007

(54) Process for conveying solid particles

(75) Inventors: Ingo Schwirtlich, Miltenberg (DE); Hilmar Von Campe, Bad Homburg (DE)

Correspondence Address: DENNISON, SCHULTZ & MACDONALD, 1727 KING STREET, SUITE 105, ALEXANDRIA, VA, 22314, US

(73) Assignee: Schott Solar Gmbh, Alzenau (DE)

(21) Appl. No.: 10/597,987

(22) PCT Filed: Mar. 8, 2005
(86) PCT No.: PCT/EP05/02413

§ 371 Date: Oct. 18, 2006

(30) Foreign Application Priority Data
Mar. 9, 2004 (EP) 04005539.4

(51) Int. Cl. H01L 21/00

(52) U.S. Cl. 438/1

(57) ABSTRACT

A process for conveying solid particles of irregular geometry, preferably polygonal geometry, through a pipe system, where the solid particles are conveyed by a gas. In order to enable metering through fragments or other solid particles of irregular geometry in desired quantities without any risk of the particles becoming trapped in the pipe system and causing blockages, further solid particles of regular geometry are added to the solids particles of irregular geometry.

The invention relates to a process for conveying solid particles of irregular geometry such as polygonal geometry through at least one pipe or pipe system having a curve or several curves and/or a kink or several kinks, where a fluid is used for conveying the solid particles.

In semiconductor technology, silicon single crystals are used as a substrate for micromechanical components or for solar cells. To manufacture silicon single crystals, the Czochralski process or the float zone process are mainly used. Occasionally, the vertical Bridgeman process or growing techniques from a metallic solution such as in liquid phase epitaxy are also used.

In solar cell production, silicon is manufactured in the form of thick blocks with a variety of block crystallization processes. In these processes, simple cooling or selective solidification of the melt results in coarse crystalline silicon blocks with grain sizes in the range from 1 mm to several centimeters.

Crystallizing silicon from the molten phase directly in the form of a wafer with a defined thickness setting is also known. This method involves so-called EFG processes, which include “Edge-Defined Film-Fed Growth” of RWE Schott Solar GmbH, linear “Continuous String Ribbon Growth” of Evergreen Solar Inc., and “Ribbon Growth on Substrates” of Bayer AG.

In EFG processes, the filling of so-called crystal growth crucibles with starting material is important to enable reproducible growth of the silicon wafers from the silicon melt present in the crucible. In systems of conventional design, corresponding crystal growth crucibles are filled manually with granules of several centimeters in size, the so-called polysilicon. This polysilicon has a high degree of purity. To manufacture solar cells by reusing silicon that has a lower purity and is that is used above all because of the low material price, fragments such as recycled wafers, flawed crystals or sawn sections such as tops and tails or side and edge pieces of crystals or sections cut from block-cast material made using the Czochralski process or the float-zone technique, flawed polysilicon rods or similar are reused in this way.

Continuous processes, in which crystalline starting material in solid or liquid form is supplied to the crucible while crystal growth is in progress are known above all from the Czochralski process and from the Edge-Defined Film-Fed Growth process. However, the latter process in particular requires the continuous supply of small crystal particles of several millimeters in size, which must be supplied to the melt during the crystallisation operation in the same quantity that material is removed from the melt by the growing crystal.

According to the prior art, spherical silicon particles are used that are separated at high temperatures from a fluidized bed by means of gas phase separation from silane at a temperature between 600° C. and 900° C. or from trichlorosilane at a temperature of 1000° C. to 1300° C. in reducing hydrogen. The particles separated from silane are currently available on a large scale. They are however very expensive because of the high purity requirements of the semiconductor industry.

The continuous refilling of crystal growth crucibles has the drawback that access to the crystal growth crucible—also known as the melting crucible—is made more difficult by the necessity for thermal shielding. As a result, special conveying techniques in a special pipe system are necessary. According to the prior art, spherical particles of defined size are supplied to the crucible via channels or by gravity by means of a gas flow inside a pipe.

U.S. Pat. No. 4,016,894 is a process for reducing drag in a turbulent aqueous stream adding a mixture of hygroscopic and hydrophobic powder. The material can be a mixture of silicon dioxide and polyethylene oxide or silicon dioxide and polyacryl amide.

From U.S. Pat No. 5,683,503 a method of promoting the flow of concrete slurry is known, where compositions are added to improve the flow. These can be sodium carbonate, polyethylene oxide, hydroxyethylcellulose or carboxymethylcellulose.

EP-A J 245 703 relates to a method for manufacturing a composite material with an Si02-containing matrix inside which a quartz glass graining is embedded.

The problem underlying the present invention is to develop a process of the type mentioned at the outset such that fragments or other solid particles having an irregular geometry can be conveyed in appropriate doses to the required extent without the risk arising of the particles becoming stuck inside the particle-carrying pipe or pipe system and thus causing stoppages.

To solve the problem, it is substantially proposed that for conveying the solid particles of irregular geometry as first solid particles, second solid particles of regular geometry are admixed with them and that the solid particles are conveyed with gas as the fluid.

In accordance with the invention, second solid particles that have a regular, such as spherical or ellipsoid, geometry are admixed as the carrier medium in addition to the conveying fluid, which is a gas, for conveying solid particles of irregular geometry. The former have the effect of improving the flowability of the first solid particles, so that it is ensured that silicon particles, for example, can be supplied to the necessary extent and in metered fashion to a melt. This offers for example the possibility of using crushed material from inexpensive silicon particles such as crystal fragments, recycled and broken wafers, broken and flawed crystals or sawn sections, to name just some examples, which are then melted.

The teachings in accordance with the invention offer a dry-conveying process for particles such as broken granulate of any form with a wide grain size spread. It is possible here to use a pipe system having kinks and bends without the risk of stoppages arising. Consequently, in the case of crystal growing, regularly shaped spherical silicon particles are conveyed into a crucible together with irregularly shaped fragments of silicon. Granulates, grains or wafer-like pieces of broken silicon material can be subsumed under irregularly shaped fragments. The starting products are CVD polysilicon rods, fragments of multicrystalline blocks, fragments and end pieces of silicon single crystals, and fragments of monocrystalline or multicrystalline wafers.

The conveying rate and the evenness of conveying depend on the proportions of large and small particles. The conveying rate falls as the proportion of irregularly shaped material rises. Prticularly good conveying results can be achieved when the proportion of first solids as the particles having an irregular outer geometry is approx. 1% to around 50% of the total quantity of first and second solid particles.

The first particles should furthermore have a grain size between 0.3 mm and 5 mm, preferably in the range between 0.5 mm and 3.0 mm.

To minimize the effect of corners and edges in the pipe system, the length-to-width ratio of the granulate should be <3. Regardless of this, the flowability is increased as the proportion of second, i.e. spherical, particles increases.

The cause of the reduction in the conveying rate with a length-to-width ratio >3 for the first solid particles is probably that in this case granules can catch and hence block the pipe or pipe system through which the particles are conveyed. If however corresponding elongated elements with a length-to-width ratio of <3 are evenly mixed with smaller flowable material, i.e. the second particles having a spherical geometry, the conveying rate improves, as in this case the first solid particles are practically surrounded by the second solid particles and are conveyed by the latter.

The invention further provides that the first solid particles have a maximum length L that is equal to or smaller than the radius of the pipe or pipe system through which the particles are conveyed.

An improvement in the conveying capacity is achieved when fluid packages, i.e. gas packages, are added for conveying, as a result of which the particles are loosened up by the fluid. As a result of this, the conveyed accumulations of solid particles undergo a change in their relative disposition to one another, so that obstacles such as bends, corners, edges or rough and uneven surfaces of the pipe or pipe system can be overcome more easily. This increases the flowability of the material. In an embodiment of the invention the fluid is supplied to the pipe in pulses. It is also possible for the solid particles to be accelerated in some sections of the pipe system. Regardless of this, it is preferably provided that the a gas comprising compressed air, nitrogen, argon and/or carbon dioxide or a mixture thereof is used as the fluid.

A further noteworthy embodiment of the invention provides that the solid particles supplied to a silicon melt are used to dope the melt. In other words, the silicon melt is doped using doping elements present in particular in the first solid particles. Highly doped silicon grains can be made here from doped left-over pieces by crushing the latter, and then mixed, in accordance with the doping required in the crystals to be grown, in a proportionate ratio with undoped solid particles having preferably a spherical geometry.

The dopants used can be boron-doped and/or phosphorus-doped materials. However, other elements of the IIIrd group of the periodic table, such as Al, Ga, In, and/or of the Vth group of the periodic table, such as As, Sb, can also be used.

The melt is doped by, for example, adding highly doped fragments in the size 0.3-10 mm, preferably 0.5-3.0 mm, of a crystal, to the non-doped material of first irregularly shaped parts and second spherical parts. This is achieved by crushing, for example, a highly doped crystal with a doping p₁ and admixing the fragments proportionately in accordance with the required doping of the melt.

Alternatively, doped material with a doping p₁ from first irregularly shaped parts and second spherical parts can also be used by mixing it with non-doped material such that a resultant doping pᵣ is achieved according to the equation:
m₁p₁+m₂p₂ . . . mₙpₙ=(m₁+m₂+ . . . +mₙ)pᵣ
where m₁ are the individual masses of the Si proportions with the respective doping P₁.

The invention is characterized in that highly doped first solid particles of the doping p⁺₁, p⁺₂, . . . p⁺ₙ of the doping concentration p⁺ᵢ with 1×10¹⁷ cm⁻³≦p⁺ᵢ≦1×10²⁰ cm⁻³, in particular with P⁺ᵢ: 1×10¹⁸ cm⁻³≦p⁺ᵢ≦1×10¹⁹ cm⁻³, in the quantities m⁺₁ bis m⁺ₙ are mixed together with second less doped solid particles of the concentrations p₁, p₂, . . . , pₘ of the doping concentration pⱼ with 1×10¹³ cm⁻³≦pⱼ≦1×10¹⁷ cm⁻³, in particular with pⱼ: 1×10¹⁴ cm⁻³≦pⱼ≦1×10¹⁶ cm⁻³ in the quantities m₁ bis mₘ such that a resultant doping of the melt pᵣ is obtained, where the following equation applies:

$${\sum }_{i = 1}^{n} {m}_{i}^{+} {p}_{i}^{+} + {\sum }_{j = 1}^{m} {m}_{j} {p}_{j} = {p}_{r} ( {\sum }_{i = 1}^{n} {m}_{i} + {\sum }_{j = 1}^{m} {m}_{j} ) .$$

In particular, the invention using a continuous process for manufacturing solid silicon by crystallization of the silicon from a silicon melt, in particular for manufacturing silicon wafers using the Edge-Defined Film-Fed Growth (EFG) process, where crystalline silicon in the form of a solid is supplied from a container to the melt, is characterized in that the solid comprises or at least contains first and second solid particles, in that the first solid particles comprise broken silicon and the second silicon particles have a spherical geometry, and in that the solid is conveyed by means of a fluid such as a gas. The solid material is here conveyed through a pipe passing through the center of the melt or being concentrically surrounded thereby. The solid particles are deflected in the direction of the container by a deflecting element arranged above the pipe and having a conical geometry. In addition, the solid particles are passed into the melt by a baffle element surrounding the pipe, passing round the outer edge in the area of the melt and having a spherical surface section geometry.

Further details, advantages and features of the invention are shown not only in the claims and in the features they contain—singly and/or in combination—but also in the following description of the preferred embodiment shown in the drawing.

The drawings show, in

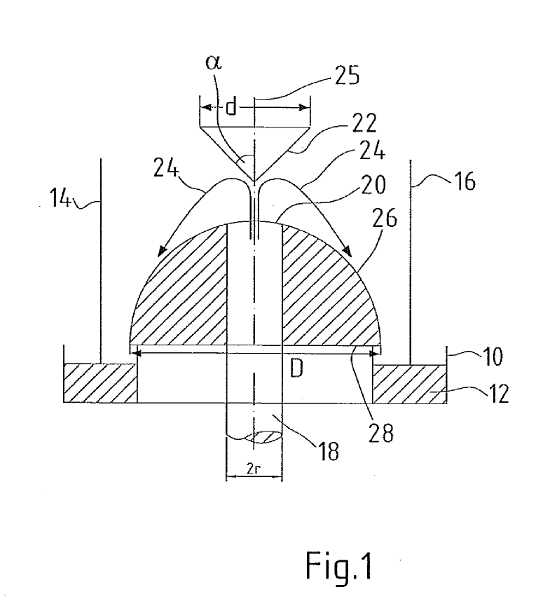

FIG. 1 a principle view of an arrangement for supplying silicon particles to a melt and

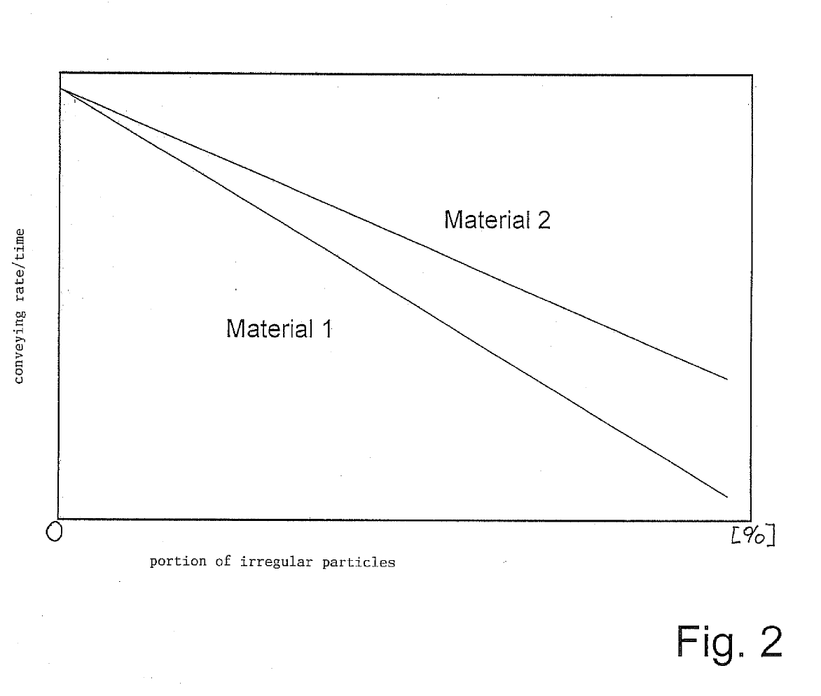

FIG. 2 a diagram of a particle-dependent conveying rate.

FIG. 1 shows purely in principle an arrangement using with the solid particles comprising or containing silicon are supplied to a silicon melt 12 inside a crucible designed as a channel 10.

A hollow element of crystallized silicon is grown from the channel 10 or silicon melt 12 using the Edge-Defined Film-Fed Growth (EFG) process. Sections, i.e. wafer-like surface portions of the hollow element are identified with the reference numbers 14 and 16. In order to supply appropriate doses of silicon particles depending on the quantity of silicon crystallized from the melt 12, a pipe system comprising a pipe section 18 is provided, through which the silicon particles are conveyed, in particular by means of a gas fluid. The pipe 18 runs along the imaginary symmetry line 25 of the channel 10. A deflecting element 22 having the geometry of an upside-down cone is provided above the pipe 18 or its opening 20. Particles conveyed out of the pipe 18 are accordingly deflected when they hit the deflecting element 22 (arrows 24), in order to be then supplied via a baffle element 26 to the melt 12. The baffle element 26 concentrically surrounds the pipe 18 and has a spherical surface section geometry, i.e. practically an umbrella geometry, the peripheral edge 28 of which ends above the melt 12. This ensures that the silicon particles passing along the surface of the baffle element 26 selectively reach the melt 12 without the risk of their hitting the hollow element of crystallized silicon.

The deflecting element 22 should in particular have an inverted circular cone form, where the angle α between lateral surfaces and central axis is 30°≦α≦60°, in particular α≈45°.

The diameter in the base area of the deflecting element 22 is d. In contrast, the baffle element 26 has at its base a diameter D. Between the diameters d and D the geometrical equation 0.2≦d/D<0.8 should apply.

The silicon material comprises first and second silicon particles of which the first particles have an irregular geometry and the second particles a spherical geometry. Thanks to the mixture of the first and second silicon particles, it is ensured that the first particles having an irregular geometry are conveyed problem-free through the pipe system incorporating bends and possibly kinks, without any risk of the particles catching on one another or building up inside the pipe. This is achieved by the second silicon particles, which act practically as the carrier substance for the first silicon particles. The first silicon particles can be in particular broken silicon material. CVD polysilicon rods, fragments of multicrystalline blocks, fragments and end pieces of silicon single crystals, and fragments of monocrystalline or multicrystalline wafers can therefore be used as starting products. This allows the use of relatively inexpensive silicon starting material for growing the silicon hollow element.

A further advantage is that the first silicon particles having an irregular surface geometry can comprise doped left-over pieces, thereby allowing selective doping of the melt 12. Possible dopants are boron and phosphorus, but also elements of the IIrd group of the periodic table, such as Al, Ga, In, or of the Vth group of the periodic table, such as As and Sb. In particular, it is possible by selective mixing of quantities of first particles containing the dopants with quantities of the second particles to inexpensively adjust the doping concentration in the melt 12 to between 1·10¹⁷ cm⁻³ and 1·10²⁰ cm⁻³, preferably in the range from 1·10¹⁸ cm⁻³ to 1·10¹⁹ cm⁻³.

To increase the conveying capacity, an in particular pulsed gas passed though the pipe system can be used as the conveying fluid. It is also possible using connections in the pipe system or changes in the pipe cross section to accelerate the particles in some sections, thereby achieving an additional mixing of the particles with one another and so allowing an improvement in the flowability.

The silicon particles or irregular geometry should have a maximum length-to-width ratio of <3. Furthermore, the maximum length should be less than the radius of the pipe 18 or the minimum radius of a section present in the pipe system.

It is furthermore provided that the temperature of the baffle 26 or deflecting element 22 is in the range between 300° C. and 1200° C., preferably between 1000° C. and 1120° C. These measures ensure that the melt 12 does not undergo a temperature change when the particles are immersed to an extent that affects the quality of the hollow element 14, 16 to be grown.

Also, the deflecting element 22 having a conical geometry and the baffle element 26 should be adapted in their geometry to the morphology and to the mixing ratio of the solid particles.

In explanation, it must be stated that the taper angle of the deflecting element should be between 30° and 45° when the irregular particles (long needles with length-to-width ratio ≈3) occur in a high mixing ratio, so that the particles are deflected horizontally as much as possible and projected along the flight parabola as far as possible over the baffle element.

The angle of the baffle element should be greater than 35°, preferably 40°, when the number of irregular particles exceeds 10%, since the irregular particles slip down without problems at angles of >40°. If the angle is <30°-40°, the material tends to stick.

Elongated particles with a width B and a length L should be dimensioned such that the length L is ≦3B. In addition, the curvature radius of the pipe in which the particles are conveyed should be at least six times the width B.

The conveying rate of the silicon particles to be supplied to the melt 12 depends on the quantity ratio between the first and second silicon particles. This is made clear in FIG. 2. Here the conveyed quantity is shown in the ratio of irregular particles to spherical particles. Material 1 has more irregular first particles than material 2. If no irregular solid particles are present in the mixture to be conveyed, the quantity conveyed per unit is the same. As the proportion of solid particles with irregular geometry increases, the conveyed quantity per unit of time decreases, with the mixture containing more irregular solid particles showing a steep decrease.

1. A process for conveying solid particles of irregular geometry through at least one pipe or pipe system having a curve or several curves and/or a kink or several kinks, where a fluid is used for conveying the solid particles,
wherein, for conveying the solid particles of irregular geometry as first solid particles, second solid particles of regular geometry are admixed with them and wherein the solid particles are conveyed with gas as the fluid.

2. Process according to claim 1,
wherein solid particles of polygonal geometry are used as the first solid particles.

3. Process according to claim 1, wherein solid particles with spherical or ellipsoid geometry are admixed as second solid particles.

4. Process according to claim 1, wherein the proportion of first solid particles is approximately 1% to about 50% of the total quantity of first and second solid particles.

5. Process according to claim 1, wherein the solid particles are conveyed by means of fluid packages.

6. Process according to claim 1, wherein the fluid is supplied to the pipe or pipe system in pulses.

7. Process according to claim 6, wherein the fluid is pulsed at regular or irregular intervals.

8. Process according to claim 1, wherein the first solid particles have an elongated form with a width B and a length L in a length-to-width ratio of L:B of about ≦3.

9. Process according to claim 1, wherein the maximum length L of the first solid particles is the radius of the pipe.

10. Process according to claim 1, wherein the first and second solid particles comprise or contain silicon.

11. Process according to claim 1, wherein broken silicon material is used as the first solid particles.

12. Process according to claim 11, wherein fragments of CVD polysilicon rods, fragments of multicrystalline blocks, fragments and/or end pieces of silicon single crystals, and fragments of monocrystalline or multicrystalline wafers are used as broken silicon material.

13. Process according to claim 1, wherein the solid particles are supplied to a silicon melt.

14. Process according to claim 13, wherein the silicon melt is doped using doping elements present in the first solid particles.

15. Process according to claim 14, wherein boron and phosphorus, elements of the IIIrd group and/or of Vth group of the periodic table are used as doping elements.

16. Process according to claim 13, wherein highly doped first solid particles of the doping p⁺₁, p⁺₂, . . . p⁻ₙ of the doping concentration p⁺ᵢ with 1×10¹⁷ cm⁻³≦p⁺ᵢ≦1×10²⁰ cm⁻³, in particular with P⁺ᵢ: 1×10¹⁸ cm⁻³≦p³⁰ ᵢ≦1×10¹⁹ cm⁻³, in the quantities m⁺₁ bis m⁺ₙ are mixed together with second less doped solid particles of the concentrations p₁, p₂, . . . , pₙ of the doping concentration pⱼ with 1×10¹³ cm⁻³≦pⱼ≦1×10¹⁷ cm⁻³, in particular with pⱼ: 1×10¹⁴ cm⁻³≦pⱼ≦1×10¹⁶ cm⁻³ in the quantities m₁ bis mₘ such that a resultant doping of the melt pᵣ is obtained, where the following equation applies:
$${\sum }_{i = 1}^{n} {m}_{i}^{+} {p}_{i}^{+} + {\sum }_{j = 1}^{m} {m}_{j} {p}_{j} = {p}_{r} ( {\sum }_{i = 1}^{n} {m}_{i} + {\sum }_{j = 1}^{m} {m}_{j} ) .$$

17. Process according to claim 1, wherein the solid particles are accelerated in one or more sections of the at least one pipe or pipe system.

18. Process for manufacturing solid silicon by crystallization of the silicon from a silicon melt, where crystalline silicon grown from the silicon melt present in a container is supplied appropriately to the silicon melt comprising or containing solid material,
wherein the solid material comprises or at least contains first and second solid particles, wherein the first solid particles comprise broken silicon material and the second solid particles have a spherical or ellipsoid geometry and wherein the solid material is conveyed by a fluid.

19. Process according to claim 18, wherein the solid material is conveyed through a pipe passing through the center of the melt or being concentrically surrounded thereby, wherein the solid particles are deflected in the direction of the container by a deflecting element arranged above the pipe and having a conical geometry, and wherein the solid particles are passed into the melt by a baffle element surrounding the pipe, passing round the outer edge in the area of the melt and having a spherical surface section geometry.

20. Process according to claim 18, wherein a gas comprising compressed air, nitrogen, argon and/or carbon dioxide or a mixture thereof is used as the fluid.

21. Process according to claim 18, wherein silicon wafers are manufactured using the Edge-Defined Film-Fed Growth process.

22. Process according to claim 19, wherein the deflecting element having a conical geometry and the baffle element are adapted in their geometry to the morphology and to the mixing ratio of the solid particles.

23. Process according to claim 19, wherein the temperature of the baffle and/or deflecting element is set in the range between 300° C. and 1200° C., preferably between 1000° C. and 1120°.

24. Process according to claim 19, wherein the deflecting element having a conical geometry has an opening angle α of preferably 30°≦α≦60°, in particular α around 45°, and at its base a diameter d and the baffle element at its base a diameter D with 0.2≦d/D ≦0.8.
